(19) United States
(12) Patent Application Publication
(10) Pub. No.: US 2003/0234597 A1
(43) Pub. Date: Dec. 25, 2003

(54) Safe actuation switches

(75) Inventor: Armand David Rosenberg, Rehovot (IL)

Correspondence Address: BAKER + HOSTETLER LLP, WASHINGTON SQUARE, SUITE 1100, 1050 CONNECTICUT AVE. N.W., WASHINGTON, DC, 20036-5304, US

(73) Assignee: Baran Advanced Technologies

(21) Appl. No.: 10/174,822

(22) Filed: Jun. 20, 2002

(51) Int. Cl. H01L 41/08

(52) U.S. Cl. 310/328

(57) ABSTRACT

A switch that is made up of a number of internal switches that receive independent inputs that, only when input in the correct sequence at the correct speed, actuate the main switch, and a method for actuating such a switch.

### FIELD OF THE INVENTION

The present invention relates generally to switches such as those in keyboards. More particularly, the present invention relates switches that are not inadvertently actuated easily.

### BACKGROUND OF THE INVENTION

Switches, such as those used in computer keyboards and telephone keypads are, most often, easily actuated. A slight, inadvertent motion on the part of a user, or an item in the user's workspace, could accidentally actuate a switch, and result in consequences ranging from minor inconvenience to significant negative impact. The user of a device that contains such a switch may be required to waste a significant amount of time and energy repairing the damage done as a result of inadvertent actuation of a switch, especially if a single actuation results in a significant action taken by the host machine.

To prevent the accidental actuation of switches, switch covers are known in the art. Switches are often covered with cups or other covers, so that a user must remove or lift the cover before actuating the switch. These switches are sub-optimal, because the switch cover is itself a moving part, and is therefore subject to wear and tear, necessitates frequent cleaning, and must be replaced often. Additionally, because a switch cover could become a nuisance to a switch user, it could be permanently removed, leaving the switch exposed, and making inadvertent actuation likely.

The majority of switches, such as those used in keyboards, are manufactured with a moveable mechanism, e.g., a key, for actuating the switch. These switches are prone to wearing out or breaking down and, thus, frequently need to be replaced. In addition, because empty space must exist between the moving parts on a keyboard, dirt and other environmental debris can accumulate and frequent cleaning is required to ensure proper functioning. Notwithstanding these drawbacks, the moveable mechanism for actuation is advantageous in that it provides tactile feedback that the switch has been actuated. For example, when a user wants to actuate a switch, the user applies pressure to the switch, and can feel the moving part of the switch move. Thus, if a switch with moving parts is actuated, even inadvertently, the user may notice by feeling the switch deform.

Switches are also known which solve many of the problems presented by the foregoing types of switches. For example, piezoelectric switches have no external moving parts and can be mounted within an enclosed casing. These switches have no external parts that can wear out and break. There are also no spaces for dirt and debris to enter into the keyboard and prevent proper operation. A drawback to these switches, however, is that they provide no discernible tactile feedback when the switch is actuated. While this is advantageous from the perspective of wear and tear, and maintenance, it is disadvantageous from the point of view of accidental actuation. Because the switch will actuate upon only the slightest pressure, such pressure is often not perceptible by the user, and switches can be actuated without knowledge or intent of the user.

Thus, there is a need in the art for switches that are durable, impervious to environmental conditions and protected from accidental actuation.

### SUMMARY OF THE INVENTION

In one aspect of the invention a switch is provided that includes a case. The case has an outer surface with a plurality of sections, and each section has the ability to receive an external force. Inside the case are a number of internal switches, and each of the internal switches has the ability to receive the external force from a particular section.

In a preferred embodiment, the internal switches have no external moving parts. In a further preferred embodiment, they are piezoelectric switches. Each internal switch has structure capable of outputting a first signal when the internal switch is actuated upon application of the external force. Also inside the case is a processor. The processor receives the first signals from the internal switches, determines a sequence in which the first signals are received, and determines a speed at which the first signals are received. The processor then compares the sequence with a specified sequence and stores a first result, and compares the speed with a specified speed and stores a second result. Finally, the processor outputs a second signal based upon the first and second results.

The switch can also contain, within the case, structure capable of transmitting the first signal from each internal switch to the processing means. The structure can be wires, cables, or any other apparatus used to transmit electrical signals. They can be arranged to connect the switch directly with the processor, they can be arranged in serial between the switches, or in any other arrangement whereby the processor can receive a signal that a particular internal switch has been actuated at a particular time. The switch also contains structure capable of receiving the second signal from the processor, and outputting an actuation signal. The output of the switch can be a wire, cable, wireless transmitter, or any other way of getting the final signal from the switch to the device with which the switch is used. In one embodiment, the switch can only be actuated when the internal switches are actuated in the order in which their counterparts appear on the case, and only at a sliding speed.

In another embodiment of the present invention, the switch contains a means for encasing internal components. The means for encasing the internal components has an outer surface, which as a plurality of sections. Each section has the ability to receive an external force. Inside the means for encasing are a number of means for detecting an external force from a particular section. Each of the internal means for detecting has the ability to receive an external force from a particular section, and each has a means for outputting a first signal when the internal means for detecting is actuated upon application of the external force. In a preferred embodiment, the means for detecting have no moving parts. In a further preferred embodiment, they are piezoelectric.

The means for encasing also contains a processing means for receiving the first signals and determining a sequence in which the first signals are received. The speed at which the first signals are received is also determined. The sequence in which the first signals are received are compared with a specified sequence and stored as a first result. The speed at which the first signals are received are compared with a specified speed and stored as a second result. A second signal is output based upon the first and second results.

The means for encasing also contains a means for transmitting the first signal from each internal switch to the processing means. These can be wires, cables, wireless transmitters, or any other device capable of transmitting signals. Finally, the means for encasing contains a means for receiving the second signal from the processing means, and outputting an actuation signal to the device in which the switch is used. In one embodiment, the switch can only be actuated when the internal switches are actuated in the order in which their counterparts appear on the case, and only at a sliding speed.

Another embodiment of the present invention is a method of actuating a switch. The method contains the steps of detecting an external force upon a particular of a plurality of sections of a case of said switch. A sequence in which said sections receive said forces is determined. A speed at which said forces are applied is also determined. The sequence is compared with a specified sequence and stored as a first result. The speed is compared with a specified speed and stored as a second result. An actuation signal is output based upon said first result and said second result. In a preferred embodiment, the switch contains internal switches containing no moving parts, and each of the internal switches corresponds to a particular sections. In a further preferred embodiment, the internal switches are piezoelectric switches. In another embodiment, the signal is output when the internal switches are actuated in order, and a speed sufficient that a sliding motion is required to actuate the switch.

There has thus been outlined, rather broadly, the more important features of the invention in order that the detailed description thereof that follows may be better understood, and in order that the present contribution to the art may be better appreciated. There are, of course, additional features of the invention that will be described below and which will form the subject matter of the claims appended hereto.

In this respect, before explaining at least one embodiment of the invention in detail, it is to be understood that the invention is not limited in its application to the arrangements of the components set forth in the following description or illustrated in the drawings. The invention is capable of other embodiments and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

FIG. 1 is a circuit diagram of a switch in accordance with a preferred embodiment of the present invention.

FIG. 2 is a top plan view of a switch in accordance with a preferred embodiment of the present invention.

### DETAILED DESCRIPTION OF PREFERRED EMBODIMENTS OF THE INVENTION

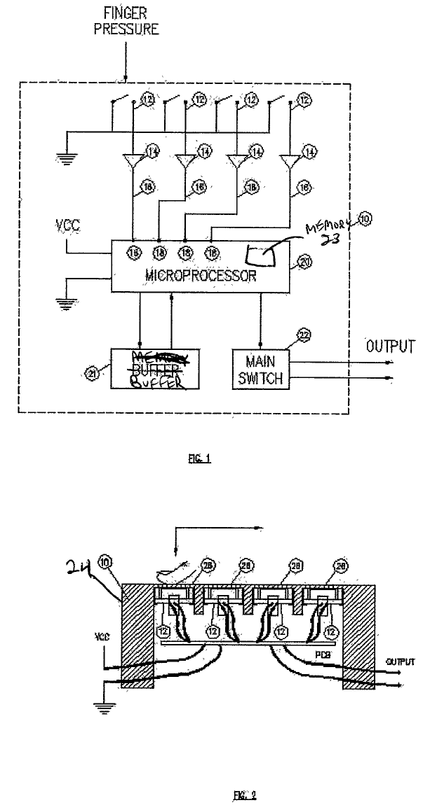

Referring now to the figures, in FIG. 1 there is shown an internal view of a switch 10 constructed in accordance with a preferred embodiment of the present invention. The switch 10 contains a number of internal switches 12. The switch 10 shows four internal switches 12, but any number of internal switches can be used. Each internal switch 12 is actuated upon receiving an external force, and, upon actuation, each switch sends a signal to its switch output 14. Connected to the switch outputs are electrical connectors 16. In accordance with a preferred embodiment, these electrical connectors are wires, but other connecting means, including cables and wireless transmission, can be used. One end of each electrical connector 16 is connected to each switch output 14, and the other end is connected to an input 18 to a microprocessor 20.

The microprocessor 20 contains firmware. The firmware is programmed to determine the sequence in which the internal switches 12 are actuated, and the speed with which they are actuated. The processing means 20, through the firmware, then compares the sequence with a specified sequence, and the speed with a specified speed. The specified sequence and the specified speed, are stored in a memory of the microprocessor 20, at some earlier time by a user wishing to program the switch. In accordance with a preferred embodiment, the processing means 20 checks to see if the sequence matches the specified sequence, and if the speed is equal to, or faster than, the specified speed. The comparison results are stored in buffers 21. If both of the buffers containing the comparison results 21 are true, the processing means 20 sends an actuation signal to the main switch output 22, which sends the signal along the other components in the system of which the switch is a part.

In FIG. 2, there is shown the outside of the main switch in accordance with the present invention. The main switch 10 is enclosed by a case 24. The outer surface of the case is divided into sections 26, and each section is capable of receiving an external force. Each of these sections is positioned in such a way as to correspond, one to one, to the internal switches 12 depicted in FIG. 1. The switch user places an external force, e.g. the push of a finger, upon a section 26 of the case 24. The section then deforms, and the corresponding internal switch 12 is actuated. The process described above, in accordance with FIG. 1, then occurs. In a preferred embodiment, the switches are piezoelectric switches such as those described in U.S. Pat. No. 4,896,069, the disclosure of which is incorporated herein by reference.

In accordance with one embodiment of the present invention, the finger must slide across each of the sections 26 in order. If the sliding is done fast enough, the comparison made in FIG. 1, with respect to the speed, is true. In an alternate embodiment, the switches must be actuated in a specified sequence. It should be readily recognized that in addition to providing a mechanism for preventing inadvertent actuation of a device, the present invention can be used to provide a security function. The number of switches that must be actuated and the sequence of actuation can be selectively programmed to prevent unauthorized actuation.

There are numerous applications envisioned for the foregoing mechanism for preventing inadvertent actuation of a switch. An example of such an application is the activation switches for machinery in a manufacturing facility. Due to the harsh environment in which these switches are placed, having a switch sealed off from contaminants such as a piezoelectric switch is advantageous. The damage that can be caused by such equipment, however, requires the use of some mechanism to prevent inadvertent activation of the switch.

Similarly, a keyboard provided in a manufacturing facility for controlling operation of machinery would recognize the same benefits from the present inventive switch. So as not to render the keyboard too cumbersome to operate, it is envisioned that the safe actuation switch of the present invention may be provided as an activation switch for enabling the keyboard in lieu of its use for each key of the keyboard. In such an application, concern would exist with a user activating the keyboard for use and then failing to deactivate it thus leaving it susceptible to inadvertent actuation of keys on the keyboard. It is therefore envisioned that activation of the safe actuation switch would trigger operation of a timer having a programmed time, e.g., one minute. Following a timing out of the timer the keyboard would be returned to an inactive mode. In this application, activation of keys on the keyboard within the programmed time would reset the timer.

The many features and advantages of the invention are apparent from the detailed specification, and thus, it is intended by the appended claims to cover all such features and advantages of the invention which fall within the true spirits and cope of the invention. Further, since numerous modifications and variations will readily occur to those skilled in the art, it is not desired to limit the invention to the exact construction and operation illustrated and described, and accordingly, all suitable modifications and equivalents may be resorted to, falling within the scope of the invention.

What is claimed is:

1. A switch comprising:
a case having an outer surface, said outer surface having a plurality of sections, each said section having the ability to receive an external force;
a plurality of internal switches inside said case, each of said internal switches having the ability to receive said external force from a particular of said plurality of sections, each of said plurality of internal switches having a signal output to transmit a first signal when said internal switch is actuated upon said application of said external force;
a processor which receives said first signals, determines a sequence in which said first signals are received, determines a speed at which said first signals are received, compares said sequence with a specified sequence and stores a first result, compares said speed with a specified speed and stores a second result, and outputs a second signal based upon said first and second results;
a signal output for transmitting said first signal from each of said plurality of internal switches to said processor;
an input for receiving said second signal from said processor, and outputting an actuation signal.

2. The switch according to claim 1, wherein said plurality of internal switches comprises a plurality of switches having no moving parts.

3. The switch according to claim 2, wherein said plurality of internal switches comprises a plurality of piezoelectric switches.

4. The switch according to claim 1, wherein said second signal is output when said sequence is equal to said specified sequence, and said speed is faster than or equal to said specified speed.

5. The switch according to claim 1, wherein said specified sequence represents each of said plurality of internal switches in the order in which said plurality of sections corresponding to each of said plurality of internal switches appear on said case, and said specified speed is sufficiently rapid so that a sliding motion on the part of the user is required to actuate the switch.

6. A switch comprising:
a means for encasing internal components having an outer surface, said outer surface having a plurality of sections, each said section having the ability to receive an external force;
a plurality of means for detecting an external force from a particular of said plurality of sections, inside said means for encasing, each of said means for detecting having the ability to receive said external force from a particular of said plurality of sections, each of said plurality having a means for outputting a first signal when said internal switch is actuated upon said application of said external force;
a processing means for receiving said first signals, determining a sequence in which said first signals are received, determining a speed at which said first signals are received, comparing said sequence with a specified sequence and storing a first result, comparing said speed with a specified speed and storing a second result, and outputting a second signal based upon said first and second results;
a means for transmitting said first signal from each of said plurality of internal switches to said processing means;
a means for receiving said second signal from said processing means, and outputting an actuation signal.

7. The switch according to claim 6, wherein said plurality of means for detecting an external force comprises a plurality of means for detecting an external force having no moving parts.

8. The switch according to claim 7, wherein said plurality of means for detecting an external force having no moving parts comprises a plurality of piezoelectric switches.

9. The switch according to claim 6, wherein said second signal is output when said sequence is equal to said specified sequence, and said speed is faster than or equal to said specified speed.

10. The switch according to claim 6, wherein said specified sequence represents each of said plurality of internal switches in the order in which said plurality of sections corresponding to each of said plurality of internal switches appear on said case, and said specified speed is sufficiently rapid so that a sliding motion on the part of the user is required to actuate the switch.

11. A method of actuating a switch comprising:
detecting an external force upon a particular of a plurality of sections of a case of said switch;
determining a sequence in which said sections receive said forces;
determining a speed at which said forces are applied;
comparing said sequence with a specified sequence and storing a first result;
comparing said speed with a specified speed and storing a second result;
outputting an actuation signal based upon said first result and said second result.

12. The method of claim 11, wherein said switch comprises internal switches containing no moving parts, and each of said internal switches corresponds to a particular of said plurality of sections.

13. The method of claim 12, wherein said internal switches comprise piezoelectric switches.

14. The method of claim 11, wherein said actuation signal is output when said sequence is equal to said specified sequence, and said speed is less than or equal to said specified speed.

15. The method of claim 11, wherein said specified sequence represents each of said plurality of internal switches in the order in which said plurality of sections corresponding to each of said plurality of internal switches appear on said case, and said specified speed is sufficiently rapid so that a sliding motion on the part of the user is required to actuate the switch.
